(19) United States
(12) Patent Application Publication
(10) Pub. No.: US 2019/0189695 A1
(43) Pub. Date: Jun. 20, 2019

(54) SELF-GENERATED LIGHTING DEVICE

(71) Applicant: Heiji NIIYAMA, Tokyo (JP)

(72) Inventor: Heiji NIIYAMA, Tokyo (JP)

(21) Appl. No.: 16/326,144

(22) PCT Filed: Aug. 15, 2017
(86) PCT No.: PCT/JP2017/029338

§ 371 Date: Feb. 15, 2019

(30) Foreign Application Priority Data
Aug. 17, 2016 (JP) 2016-171256

(51) Int. Cl. H01L 27/28; G02F 1/1335; H01G 9/20; H02S 40/22; H02S 40/32; H02S 40/38; H02J 7/35; H02J 7/00; G09F 13/18

(52) U.S. Cl. CPC H01L 27/288; G02F 1/133603; H01G 9/2059; H02S 40/22; H02S 40/32; G09F 2013/1881; H02J 7/35; H02J 7/0029; G09F 13/18; H02J 2007/0037; H02S 40/38

(57) ABSTRACT

A self-generated lighting device, including: a frame, light source, solar cell, display panel, light guide plate, light reflecting plate, power control unit, and power storage device, wherein the power control unit controls electric power supplied to the light source and includes at least commercial electric power. The power storage device includes a power storage battery that stores electricity from the control unit, and supplies the electric power stored to the light source. The light source emits light energy toward a confronting side from one end side of an installation area in a frame, and the light guide plate guides the light energy emitted toward the display panel, and the light reflecting plate reflects the light energy toward the display panel, the light energy being guided toward a bottom surface portion of the light guide plate. The solar cell absorbs light energy of both direct and reflected light to generate electricity.

### TECHNICAL FIELD

The present invention relates to a self-generated lighting device capable of absorbing light energy emitted from a light source inside and outside of a frame by a solar cell, to self-generate a photovoltaic power by a photovoltaic effect.

### DESCRIPTION OF RELATED ART

Until now, photovoltaic power generation is a device that absorbs UV lights and light energy of daytime sunlight and self-generates photovoltaic power by the photovoltaic effect as its name suggests, and there has been no high interest in power generation of reusing light energy radiated from a light source for illumination instead of the daytime sunlight.

In recent years, as a light source for signboard illumination, a signboard illumination device using a LED (Light Emitting Diode) light source instead of a fluorescent lamp or a mercury lamp has been disclosed by the present inventor (see Patent Document 1).

Further, transparent solar cells utilizing daytime sunlight are also disclosed (see Patent Documents 2, 3, 4).

### PRIOR ART DOCUMENT

### Patent Document

[Patent Document 1] Japanese Patent No. 55925228

[Patent Document 2] Japanese Patent Application Laid-Open No. 2005-129987

[Patent Document 3] Japanese Patent Application Laid-Open No. 2009-229975

[Patent Document 4] Japanese Patent Application Laid-Open No. 2011-119455

### SUMMARY OF THE INVENTION

### Problem to be Solved the Invention

So far, much efforts are made to reduce power consumption of a light source for illumination, but it has been neglected to effectively reuse a self-radiated light energy by the light source for illumination.

In the signboard illumination device described in Patent Document 1, although much efforts are made to reduce power consumption by averaging the brightness of an entire signboard surface, there is no mentioning about the effective reuse of the light energy radiated from a LED light source.

In a mobile phone described in Patent Document 2, a problem is that there is a large variation in power generation amount due to weather, because the light energy of sunlight is used, although an entire housing is constituted of a transparent solar cell.

Further, in an electric bulletin board described in Patent Document 3, a problem is that power generation amount is extremely reduced in a case of rainy weather etc., because the light energy of sunlight is used as described above.

Further, in an organic EL device including a solar cell described in Patent Document 4, a problem is that there is a variation in power generation capacity due to the weather and stable power generation cannot be expected, because the light energy of daytime sunlight is absorbed to generate electricity.

An object of the present invention is to provide a self-generated lighting device capable of not only emitting light energy radiated from a light source for illumination but also reusing the emitted light energy to self-generate electricity, and capable of realizing further power saving, in view of an experience the fact that the charged amount of a mobile terminal etc., becomes 0 because of a long-term power failure due to an accident at nuclear power plants in Fukushima Prefecture, and a user has to visit a place where there is no power failure to recharge electricity, and a surge of electricity price and a consciousness of power saving thereafter.

### Means for Solving the Problem

### (First Aspect)

According to a first aspect of the present invention, there is provided a self-generated lighting device, including:

a frame having an opening as an installation area in which an object to be irradiated is installed;

a light source for illumination which is provided in the frame, and emits light upon receiving supply of electric power;

a solar cell that absorbs light energy to generate electricity;

a display panel which is installed in the installation area in the frame as the object to be irradiated, and which displays a predetermined image upon receiving supply of the light energy emitted from the light source;

a light guide plate provided in the frame;

a light reflecting plate formed on a bottom surface portion of the light guide plate;

a power control unit that controls electric power supplied to the light source and includes at least commercial electric power as one of electric powers to be controlled; and

a power storage device that includes a power storage battery that stores electricity upon receiving supply of the electric power from the power control unit, and supplies the electric power stored in the power storage battery to the light source,

wherein the light source is provided at one end of the installation area in the frame, and emits light energy toward a confronting side from the one end side,

the light guide plate guides the light energy emitted from the light source toward the display panel, and

out of the light energy emitted from the light source, the light reflecting plate reflects the light energy toward the display panel, the light energy being guided toward a bottom surface portion of the light guide plate, and

the solar cell absorbs light energy of both direct light from the light source and reflected light from the light reflecting plate, to generate electricity.

### (Second Aspect)

According to a second aspect of the present invention, there is provided a self-generated lighting device, including:

a frame having an opening area as an installation area in which an object to be irradiated is installed;

a light source for illumination which is provided in the frame, and emits light upon receiving supply of electric power;

a solar cell that absorbs light energy to generate electricity;

a display panel which is installed in the installation area in the frame as the object to be irradiated, and which displays a predetermined image upon receiving supply of the light energy emitted from the light source;

a light reflecting plate provided in the frame;

a power control unit that controls electric power supplied to the light source and includes at least commercial electric power as one of electric powers to be controlled; and

a power storage device that includes a power storage battery that stores electricity upon receiving supply of the electric power from the power control unit, and supplies the electric power stored in the power storage battery to the light source,

wherein the light source is provided at one end of the installation area in the frame, and emits light energy toward a confronting side from the one end side,

the light reflecting plate has a reflecting surface disposed to face the display panel, with the reflecting surface set obliquely inclined so that a distance between the reflecting surface and the display panel is gradually decreased from one end of the installation area toward the other end confronting thereto, and so that a part of the light energy emitted from the light source, is reflected by the reflecting surface toward the display panel, and

the solar cell absorbs the light energy of both direct light emitted from the light source and reflected light emitted from the light source and reflected by the reflecting surface toward the display panel, to generate electricity.

### (Third Aspect)

According to a third aspect of the present invention, there is provided a self-generated lighting device, including:

a frame having an opening area as an installation area;

a self-luminous panel which is installed in the installation area in the frame and emits light upon receiving supply of electric power;

a solar cell that absorbs light energy to generate electricity;

a power control unit that controls electric power supplied to the panel and includes at least commercial electric power as one of electric powers to be controlled; and

a power storage device that includes a power storage battery that stores electricity upon receiving supply of the electric power from the power control unit, and supplies the electric power stored in the power storage battery to the panel,

wherein the solar cell includes at least a first solar cell among a transparent first solar cell formed in a planar shape on an outer surface of the panel with its light absorption surface facing inward; a transparent second solar cell formed in a planar shape on the outer surface of the panel with its light absorption surface facing outward, and a transparent or opaque third solar cell formed in a planar shape on a surface opposite to the opening of the installation area in the frame,

the first solar cell is disposed in a light emitting direction of the panel, and absorbs light energy emitted from the panel to generate electricity,

when the solar cell includes the second solar cell and the third solar cell, the second and third solar cells absorb light energy from sunlight or outdoor lighting to generate electricity, and absorb light energy from indoor lighting to generate electricity, and

the power storage device stores electricity in the power storage battery upon receiving supply of the electric power from the power control unit, the electric power being generated by at least one solar cell among the first solar cell, the second solar cell, and the third solar cell.

### Advantage of the Invention

According to the present invention, it is possible to provide a self-generated lighting device capable of reusing light energy emitted from a light source for illumination to self-generate electricity, and capable of realizing further power saving.

### BRIEF DESCRIPTION OF THE DRAWINGS

FIG. 1A is a schematic plan view showing a configuration of a surface mount-type LED package.

FIG. 1B is a cross-sectional view taken along the line A-A of FIG. 1A.

FIG. 1C is a cross-sectional view showing another configuration of the surface mount-type LED package.

FIG. 2 is a schematic perspective view showing an arrangement of a liquid crystal panel, a transparent UV cut film, an organic thin film transparent solar cell, and a light source.

FIG. 3A is a schematic perspective view of a purple LED module including a frame of a self-generated lighting device according to a first embodiment of the present invention.

FIG. 3B is a sectional view taken along the line A-A of FIG. 3A.

FIG. 3C is a schematic view showing a configuration example of an electric circuit of a self-generated lighting device according to a first embodiment of the present invention.

FIG. 4A is a perspective view including a frame of a self-generated lighting device (power saving type multi-row LED lighting fixture) according to a second embodiment of the present invention.

FIG. 4B is a cross-sectional view taken along the line A-A of FIG. 4A.

FIG. 4C is a schematic view showing a configuration example of an electric circuit of a self-generated lighting device according to a second embodiment of the present invention.

FIG. 5A is a schematic perspective view including a frame of a self-generated lighting device according to a third embodiment of the present invention.

FIG. 5B is a cross-sectional view taken along the line A-A of FIG. 5A.

FIG. 5C is a schematic view showing a configuration example of an electric circuit of a self-generated lighting device according to a third embodiment of the present invention.

FIG. 6A is a schematic perspective view including a frame of a self-generated lighting device according to a fourth embodiment of the present invention.

FIG. 6B is a cross-sectional view taken along the line A-A of FIG. 6A.

FIG. 6C is a schematic view showing a configuration example of an electric circuit of the self-generated lighting device according to the fourth embodiment of the present invention.

### DETAILED DESCRIPTION OF THE INVENTION

Hereinafter, embodiments of the present invention will be described in detail with reference to the drawings. Note that in the specification of the present application, all the matters described in the specification, the scope of claims and the drawings of the basic application No. 2016-171256 are stated without omission, and the matters disclosed in the basic application can be added to the specification, claims, and drawings of the present application as necessary.

### (Configuration of LED Package)

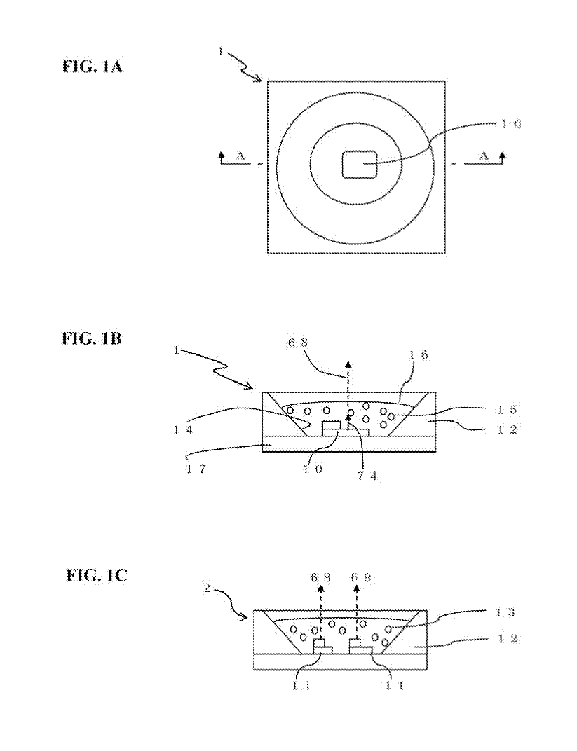

First, a configuration of an LED package used in an embodiment of the present invention will be described with reference to FIGS. 1A, 1B, and 1C. FIG. 1A is a schematic plan view showing a configuration of a surface mount-type LED package, and FIG. 1B is a cross-sectional view taken along the line A-A of FIG. 1A.

In this embodiment, as shown in FIG. 1A and FIG. 1B, a surface mount-type purple LED package 1 is used as an LED package. The purple LED package 1 includes: a cavity 12 molded from ceramic or resin; a purple LED element 10 mounted in the cavity 12; a reflector 14 formed on the inner surface of the cavity 12; a sealing material 15 filling the inside of the cavity 12; a condenser lens 16; and LED substrate 17. The sealing material 15 and the condenser lens 16 are stacked in this order on the purple LED element 10.

The reflector 14 reflects purple light energy 74 emitted from the purple LED element 10 to a front surface (upward in FIG. 1B).

The sealing material 15 seals the purple LED element 10, and includes a silicone resin containing R (red) G (green) B (blue) phosphors. For the sealing material 15, it is preferable to use a silicone resin having ultraviolet resistance and heat resistance in which RGB phosphors for simultaneous additive color mixture are dispersed.

The purple LED element 10 is mounted on the LED substrate 17. The purple LED element 10 radiates purple light energy 74. The purple LED package 1 emits and radiates the purple light energy 74 emitted from the purple LED element 10 and simultaneous additive white light energy 68 obtained by combining with RGB phosphors contained in the sealing material 15, together with UV light (UV light energy).

Further, in the purple LED package 1, white light energy 68 for obtaining the whole visible light region with phosphor emission, is realized by radiating the purple light energy 74 emitted from the purple LED element 10 toward the RGB phosphors contained in the sealing material 15, that is, by simultaneous additive color mixture utilizing three primary colors of light. Therefore, color reproducibility is much higher, and it is easy to approximate Ra (average color rendering index) to 100 by adjusting increase/decrease of each phosphor of RGB, compared to a method of emitting and radiating pseudo white light in a combination of a blue LED element and a yellow phosphor which have been mainstream so far. Further, light emission of light energy such as red, green, blue, yellow, etc. other than white light can be easily controlled by adjusting the increase/decrease of each phosphor of RGB. Further, the purple light energy 74 is radiated from the purple LED element 10 as the light energy 68 for emitting white light by simultaneous additive color mixture with RGB phosphors, or for emitting a color that can be obtained by the simultaneous additive color mixture. The purple light energy 74 is also radiated as UV lights (UV light energy).

In this embodiment, the purple LED element 10 is employed as the LED element. However, other LED elements, for example, a near UV light LED element, a blue LED element, or a near infrared LED element may also be employed. Further, in this embodiment, a face-up type is employed as a mounting structure of the purple LED element 10 mounted in the cavity 12 on the LED substrate 17. However, face-down type may also be employed.

Further, as shown in FIG. 1B and FIG. 1C, the number of the purple LED elements used for the LED package may be one or plural. The condenser lens 16 may be attached to the blue LED package 2, but it is not indispensable as the blue LED package 2 or the purple LED package 1, and may be provided as necessary.

Further, in an aspect shown in FIG. 1B, purple LED element and RGB phosphor are used. However, the LED element and the phosphor are not limited thereto, and as shown in FIG. 1C, the light energy 68 may be emitted by the blue LED package 2 in which the blue LED element 11 and a yellow phosphor-containing sealing member 13 are combined. In this case, as the sealing material 13, it is preferable to use a heat-resistant silicone resin in which the yellow phosphor is dispersed. Further, the combination of the blue LED element 11 and the yellow phosphor-containing sealing material 13 hardly radiates UV lights, and therefore measures against UV lights are not so necessary.

### (Configuration of Transparent Solar Cell)

The sunlight falling from the sun to the ground includes wavelength light of about 50% visible light, about 44% infrared light and about 6% UV light. The current transparent solar cell is configured to absorb visible light and UV light, or visible light and infrared light from the wavelength light included in sunlight, to generate a photovoltaic power by a photovoltaic effect.

### (Configuration of Liquid Crystal Panel, Transparent UV Cut Film, Organic Thin Film Transparent Solar Cell and Light Source)

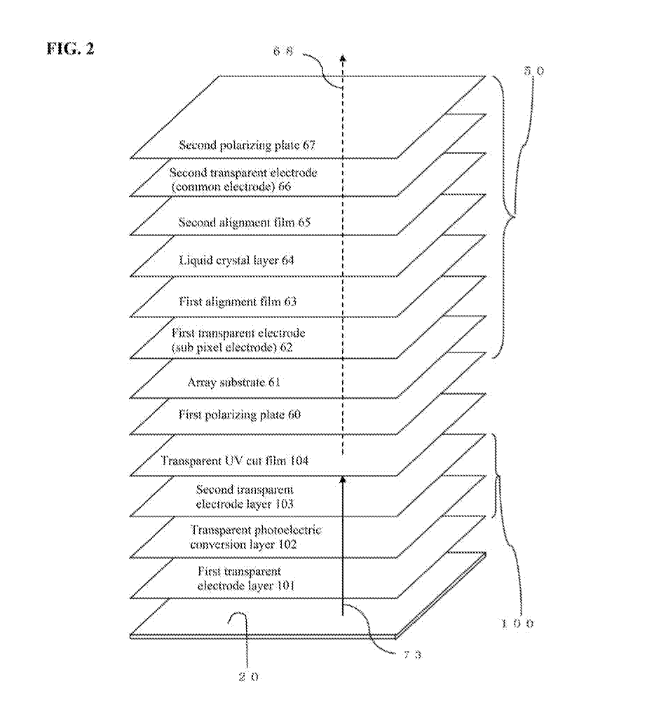

FIG. 2 is a schematic perspective view showing the arrangement of a liquid crystal panel, a transparent UV cut film, an organic thin film transparent solar cell and a light source.

As shown in FIG. 2, an organic thin film transparent solar cell 100, a transparent UV cut film 104, and a liquid crystal panel 50 are stacked in this order, in a light emitting direction of a purple LED module 20 which is a light source. In this case, the purple LED module 20 constitutes a light source for backlight of the liquid crystal panel 50. The backlight has direct type and edge light-type, and either one may be employed, but in this embodiment, the direct type is employed as an example. Namely, the purple LED module 20 is formed by connecting a plurality of the above-described surface mount-type purple LED packages 1. The term “connecting” means a state in which purple LED packages 1 are arranged to be continuous with each other and are electrically connected. The direct type backlight is configured by arranging a plurality of purple LED packages 1 in a two-dimensional (matrix) manner at predetermined intervals. The purple LED module 20 also radiates UV light (UV light energy 73) together with the white light energy 68 by simultaneous additive color mixture.

As shown in FIG. 2, the organic thin film transparent solar cell 100 is constituted of a first transparent electrode layer 101, a transparent photoelectric conversion layer 102, and a second transparent electrode layer 103, as seen from the purple LED module 20, and are stacked in this order. The organic thin film transparent solar cell 100 generates high photovoltaic power by adjusting an amount of UV light by increase/decrease of each phosphor of RGB. The organic thin film transparent solar cell 100 absorbs the UV light energy 73 radiated from the purple LED module 20 to generate electricity by the photovoltaic effect. The photovoltaic power which is self-generated by the organic thin film transparent solar cell 100 is supplied to the purple LED module 20 via a DC controller not shown, or stored in a secondary lithium ion storage battery (not shown).

Note that a voltage of the photovoltaic power which is self-generated by the organic thin film transparent solar cell 100 is affected by an amount of incident light of the UV light energy 73, and therefore it is impossible to use the voltage as it is. Therefore, a DC controller is provided, to control the voltage generated by the organic thin film transparent solar cell 100 so as to be compatible with a scheduled supply destination. The DC controller controls the generated voltage so that the supply destination of the voltage generated by the organic thin film transparent solar cell 100 is compatible with each supply destination, for example, the generated voltage is compatible with each supply destination of the purple LED element 10, the lithium ion storage battery or the like. Namely, after the voltage generated by the organic thin film transparent solar cell 100 is controlled by the DC controller, the generated voltage is supplied to the purple LED module 20, or stored in the secondary lithium-ion battery.

The transparent UV cut film 104 is formed just outside the organic thin film transparent solar cell 100 as seen from the purple LED module 20. The transparent UV cut film 104 absorbs and eliminates UV lights after being absorbed but not fully absorbed by the organic thin film transparent solar cell 100 to generate photovoltaic power. Thereby, the transparent UV cut film 104 suppresses a bad influence of radiating UV lights toward a lamp cover 105 of the liquid crystal panel 50 or a human body existing in front of the transparent UV cut film 104, by transmitting the white light energy 68 as it is not containing UV light.

Note that in this embodiment, the transparent UV cut film 104 is employed. However, any other material may be used as long as it is transparent and absorbs and eliminates UV lights. Further, if the organic thin film transparent solar cell 100 absorbs the UV lights to some extent and there is little influence of emitting UV lights toward the liquid crystal panel 50 or the human body existing outside the organic thin film transparent solar cell 100, it is not necessary to provide the transparent UV cut film 104.

The liquid crystal panel 50 is configured so that a first polarizing plate 60, an array substrate 61, a first transparent electrode (sub pixel electrode) 62, a first alignment film 63, a liquid crystal layer 64, a second alignment film 65, a second transparent electrode (common electrode) 66, and a second polarizing plate 67, are stacked in this order as seen from the purple LED module 20. The UV light energy 73 emitted and radiated from the purple LED module 20 which is a light source, is incident on the liquid crystal panel 50 through the organic thin film transparent solar cell 100 and the transparent UV cut film 104. A part of the UV light energy 73 emitted from the purple LED module 20 is absorbed by the organic thin film transparent solar cell 100. The transparent UV cut film 104 absorbs and eliminates the remaining ultraviolet lights which cannot be completely absorbed by the organic thin film transparent solar cell 100. Therefore, the light incident on the liquid crystal panel 50 becomes the light energy 68 not containing the UV lights, and by supplying the light energy 68, the liquid crystal panel 50 is lighted up. The light energy 68 lighting up the liquid crystal panel 50 becomes visible light and eventually disappears.

### First Embodiment

Hereinafter, a self-generated lighting device according to a first embodiment of the present invention will be described.

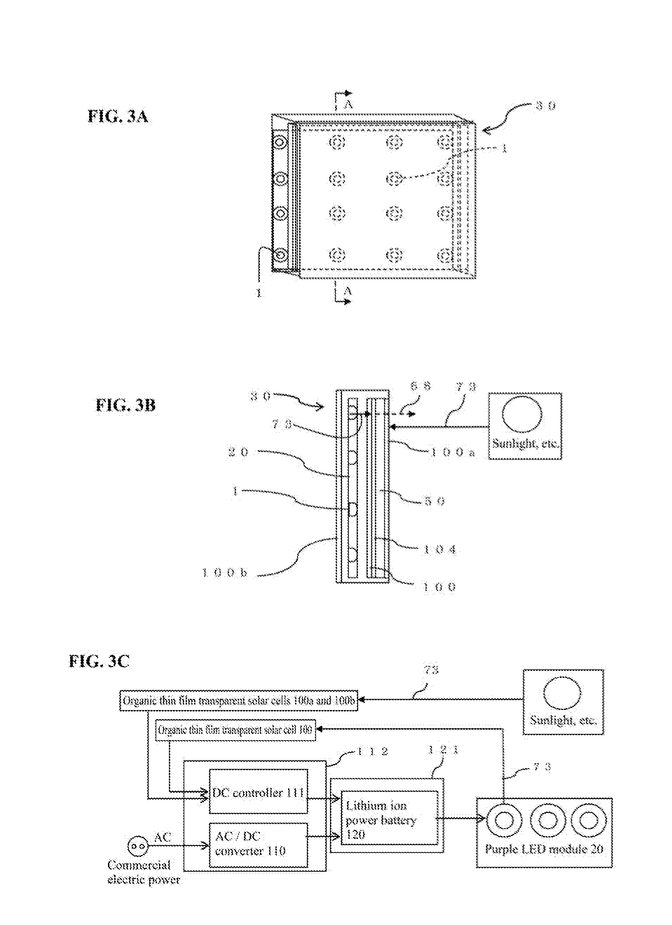

FIG. 3A is a schematic perspective view of a purple LED module including a frame of a self-generated lighting device according to a first embodiment of the present invention. Further, FIG. 3B is a cross-sectional view taken along the line A-A of FIG. 3A, and FIG. 3C is a schematic view showing a configuration example of an electric circuit of the self-generated lighting device according to the first embodiment of the present invention.

The self-generated lighting device shown in the figure, includes: the purple LED module 20; the frame 30; the liquid crystal panel 50; the organic thin film transparent solar cells 100, 100a, 100b, and the transparent UV cut film 104.

As described above, the purple LED module 20 is a light source for backlight which is formed by connecting a plurality of surface mount-type purple LED packages 1 as described above.

The frame 30 has an opening area as an installation area in which the liquid crystal panel 50 to be irradiated and the other equipment are installed, and the organic thin film transparent solar cells 100, 100a and the transparent UV cut film 104 are installed, together with the liquid crystal panel 50. Further, the purple LED module 20 (purple LED package 1) is installed in the frame 30, and an organic thin film transparent solar cell 100b is installed on the back side (the side opposite to the opening of the installation area) of the frame 30.

The liquid crystal panel 50 displays a predetermined image (still image, moving image, etc.), upon receiving supply of the light energy emitted from each purple LED package 1 of the purple LED module 20.

Each of the organic thin film transparent solar cells 100, 100a, 100b is formed in a planar shape. The organic thin film transparent solar cell 100 absorbs the UV light energy 73 emitted and radiated from each of the plural purple LED packages 1 connected to the purple LED module 20, to self-generate the photovoltaic power by the photovoltaic effect. The organic thin film transparent solar batteries 100a, 100b absorb the UV light energy 73 from sunlight or outdoor lighting (street lamp, mercury lamp, etc.), to self-generate the photovoltaic power by the photovoltaic effect.

The organic thin film transparent solar cell 100 is disposed in the frame 30 so as to face the purple LED module 20. The organic thin film transparent solar cell 100 is disposed on the inner surface of the liquid crystal panel 50 interposing the transparent UV cut film 104, and the organic thin film transparent solar cell 100a is disposed on the outer surface of the liquid crystal panel 50. Thereby, the UV light energy 73 emitted from each purple LED package 1 of the purple LED module 20, is absorbed by the organic thin film transparent solar cell 100, and the UV light which cannot be completely absorbed there, is absorbed and eliminated by the transparent UV cut film 104. Accordingly, the liquid crystal panel 50 is irradiated with the light energy 68 not containing the UV light.

The transparent UV cut film 104 is formed just outside the organic thin film transparent solar cell 100, as seen from the surface mount-type purple LED package 1. The transparent UV cut film 104 absorbs and eliminates the UV light transmitted through the organic thin film transparent solar cell 100. The transparent UV cut film 104 absorbs and eliminates the remaining UV light after being absorbed by the organic thin film transparent solar cell 100 to generate photovoltaic power, and transmits the light energy 68 as it is not containing UV light. Thereby, the transparent UV cut film 104 suppresses a bad influence of emitting UV lights toward the liquid crystal panel 50 or the human body existing in front of the transparent UV cut film 104.

Note that this embodiment employs a configuration in which three organic thin film transparent solar cells 100, 100a, and 100b are combined, but the configuration is not limited thereto, and it is also acceptable to employ a configuration using the organic thin film transparent solar cell 100 alone, a configuration of combining the organic thin film transparent solar cell 100 and the organic thin film transparent solar cell 100a, or a configuration in which the organic thin film transparent solar cell 100 and the organic thin film transparent solar cell 100b are combined.

### (Electric Circuit)

The power control unit 112 controls the electric power to be supplied to the purple LED module 20 (purple LED package 1) which is the light source, and includes a commercial electric power as one of the electric powers to be controlled, and has AC/DC converter 110 and a DC controller 111. The power control unit 112 captures the commercial electric power generated by the transparent solar cells 100, 100a, 100b, and supplies the captured electric power to the power storage device 121. The AC/DC converter 110 converts it into DC power, upon receiving supply of the commercial electric power (AC). The DC power converted by the AC/DC converter 110 is stored in the lithium ion storage battery 120 of the power storage device 121. The DC controller 111 controls the photovoltaic power generated by the transparent solar cells 100, 100a, 100b so as to compatible with the purple LED module 20. The electric power controlled by the DC controller 111 is stored in the lithium ion storage battery 120 of the power storage device 121.

The power storage device 121 includes a lithium ion storage battery 120 that stores electricity upon receiving electric power from the power control unit 112, and supplies the electric power stored in the lithium ion storage battery 120 to the purple LED package 1 of the purple LED module 20. The lithium ion storage battery 120 stores the electric power supplied from the AC/DC converter 110 and the DC controller 111 of the power control unit 112. The electric power stored in the lithium ion storage battery 120 is supplied to the purple LED module 20. The electric power supplied to the purple LED module 20 is consumed to cause each purple LED package 1 to emit light (light up the purple LED module 20).

Further, when a charged amount of the lithium ion battery 120 reaches a fully charged state upon receiving supply of the electric power from the power control unit 112, the power storage device 121, by itself, has an overcharge prevention function of stopping supply of the electric power from the power control unit 112.

In the first embodiment of the present invention, each purple LED package 1 emits the UV light energy 73 when the power device 121 supplies the commercial electric power stored in the lithium ion storage battery 120 to the purple LED module 20 via the AC/DC converter 110. Then, the organic thin film transparent solar cell 100 absorbs the UV light energy 73 emitted from each purple LED package 1, to generate the photovoltaic power by the photovoltaic effect. The electric power generated by the organic thin film transparent solar cell 100 is stored in the lithium ion storage battery 120, and is used for light emission by the purple LED package 1. Thereby, the light energy emitted by the purple LED package 1 is reused by the organic thin film transparent solar cell 100 to self-generate electric power, and it is possible to realize further power saving.

Meanwhile, the organic thin film transparent solar cell 100a and the organic thin film transparent solar cell 100b respectively absorbs the UV light energy 73 from sunlight by being exposed to daylight sunlight, to generate the photovoltaic power by the photovoltaic effect. Further, the organic thin film transparent solar cell 100a and the organic thin film transparent solar cell 100b respectively absorbs the UV light energy 73 emitted from outdoor lighting or indoor lighting at night, to generate the photovoltaic power by the photovoltaic effect. The photovoltaic power generated by the organic thin film transparent solar cells 100, 100a in this manner, is captured into the power storage device 121 via the DC controller 111, and is stored in the lithium ion storage battery 120. Thereby, it is possible to achieve a long life of the discharge capacity of the lithium ion storage battery 120. Further, even if supply of the commercial electric power is cut off due to long-term disaster or the like and an amount of the stored electricity in the lithium ion storage battery 120 becomes 0, it is possible to restore the lost charged amount of the lithium ion storage battery 120 by storing therein the photovoltaic power which is self-generated by absorbing the UV light energy 73 from the sunlight by at least one of the organic thin film transparent solar cell 100a and the organic thin film transparent solar cell 100b.

Note that when the photoelectric conversion efficiency of the organic thin film transparent solar cells 100, 100a, 100b used in this embodiment is greatly improved, it is also possible to eliminate the need for recharging with the commercial electric power. Further, in this embodiment, the solar cell installed on the back side of the frame 30 is the organic thin film transparent solar cell 100b, but this may not be transparent but may be an opaque solar cell with excellent photoelectric conversion efficiency. This point also applies to the other embodiments described below.

Further, in the above-described first embodiment, the purple LED module (purple LED package) is used as an LED module (LED package) which is a light source for illumination, but the LED module is not limited thereto, and a near-UV light LED module (near UV light LED package), a blue LED module (blue LED package), a near-infrared LED module (near-infrared LED package), or the like may also be used. Further, in the first embodiment, the lithium ion storage battery is used as an example of the storage battery (secondary battery), but other storage batteries (for example, lead storage battery, nickel storage battery, etc.) may also be used as long as the storage capacity and charge/discharge capacity are excellent. Further, in the above-described first embodiment, the organic thin film transparent solar cell is used as a transparent solar cell, but the transparent solar cell is not limited thereto, and transparent solar cells such as organic transparent solar cells including dye sensitized transparent solar cells, transparent innovative solar cells, transparent compound-based solar cells, and transparent thin-film solar cells, can be widely used.

### Second Embodiment

Next, a self-generated lighting device according to a second embodiment of the present invention will be described.

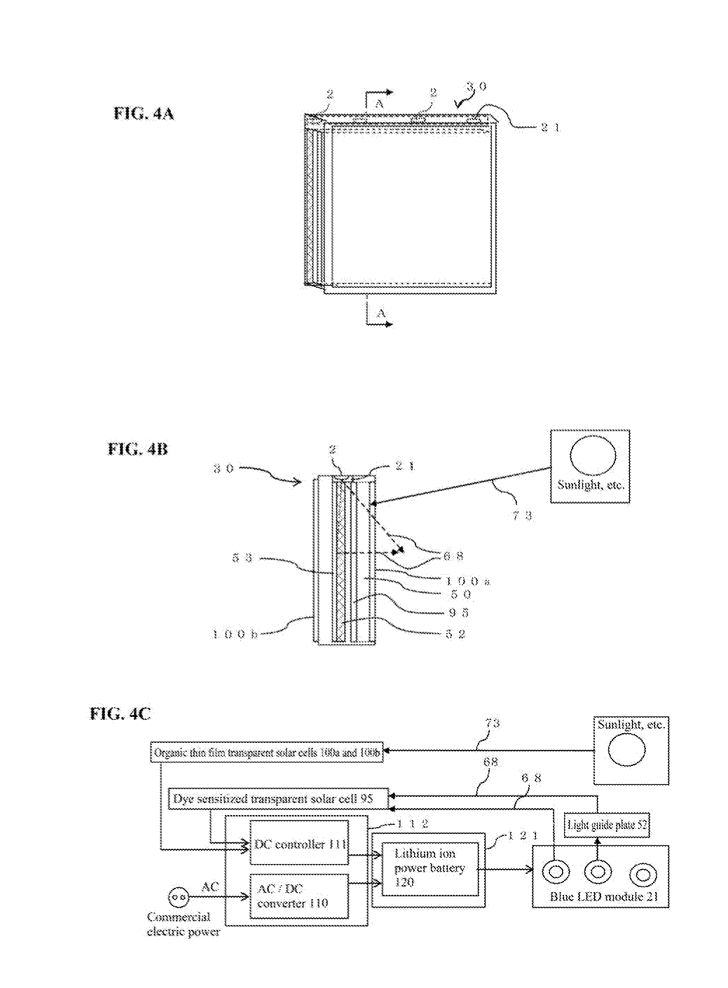

FIG. 4A is a schematic perspective view including a frame of a self-generated lighting device according to a second embodiment of the present invention. Further, FIG. 4B is a cross-sectional view taken along the line A-A of FIG. 4A, and FIG. 4C is a schematic view showing a configuration example of an electric circuit of the self-generated lighting device according to a second embodiment of the present invention. Note that in this second embodiment, elements that are different from those of the first embodiment will be mainly described, elements that are substantially the same as the elements described in the first embodiment will be given the same reference numerals, and description thereof will be omitted as much as possible.

The self-generated lighting device according to the second embodiment of the present invention includes: a blue LED module 21, a frame 30, a liquid crystal panel 50, a light guide plate 52, a light reflecting plate 53, a dye sensitized transparent solar cell 95, and organic thin film transparent solar cells 100a, 100b.

The blue LED module 21 is formed by connecting a plurality of surface mount-type blue LED packages 2. The blue LED module 21 is a light source constituting an edge light-type backlight. The blue LED module 21 is provided at one end (an upper part in this embodiment) of an installation area within the frame 30, and emits and radiates the light energy 68 to the confronting side from the one end side.

The frame 30 has an opening area as an installation area in which the liquid crystal panel 50 to be irradiated and the other equipment are installed, and the dye sensitized transparent solar cell 95 and the organic thin film transparent solar cell 100a are installed, together with the liquid crystal panel 50. Further, the light guide plate 52 is installed in the frame 30, together with the blue LED module 21 serving as a light source for illumination. The light guide plate 52 is installed so as to face the dye sensitized transparent solar cell 95, the light reflecting plate 53 is provided on one main surface (hereinafter referred to as a bottom surface) of the light guide plate 52.

The liquid crystal panel 50 displays a predetermine image (still images, moving images, etc.) upon receiving supply of the light energy emitted from each blue LED package 2 of the blue LED module 21 and guided by the light guide plate 52 and the light reflecting plate 53. The liquid crystal panel 50 is installed in the installation area in the frame 30 as an object to be irradiated. The object to be irradiated is an object to be irradiated with light emitted from a light source for illumination (in this embodiment, the blue LED module 21).

The light guide plate 52 efficiently guides the light energy 68 incident from the side surface of the light guide plate 52 toward the liquid crystal panel 50 side, for example, by applying laser processing, etching processing or the like to a plastic plate such as an acrylic plate. Therefore, when the light energy 68 is incident on the light guide plate 52 from the blue LED module 21, the light energy 68 is radiated (surface light-emitting) from a plate surface of the light guide plate 52 that faces the liquid crystal panel 50.

Out of the light energy 68 incident on the light guide plate 52 from the blue LED module 21, the light reflecting plate 53 forcibly reflects the light energy 68 guided to the bottom surface side of the light guide plate 52 toward the liquid crystal panel 50 side, and has a reflecting surface for that purpose. The reflecting surface of the light reflecting plate 53 is disposed in close contact with or close to the bottom surface of the light guide plate 52.

The dye-sensitized transparent solar cell 95 and the organic thin-film transparent solar cells 100a, 100b are each formed in a planar shape. The dye sensitized transparent solar cell 95 is disposed on the inner surface of the liquid crystal panel 50 so as to face the light guide plate 52, and the organic thin film transparent solar cell 100a is disposed on the outer surface of the liquid crystal panel 50. Further, the organic thin film transparent solar cell 100b is installed on the back side (the side opposite to the opening of the installation area) of the frame 30.

The dye sensitized transparent solar cell 95 absorbs the light energy 68 emitted and radiated from each of the plurality of blue LED packages 2 connected to the blue LED module 21, to self-generate the photovoltaic power by the photovoltaic effect. Specifically, the dye sensitized transparent solar cell 95 absorbs the light guided from the blue LED module 21 to the liquid crystal panel 50 side by the light guide plate 52 to generate electricity, and in addition, absorbs the light energy 68 of both the direct light from the blue LED module 21 and the reflected light from the light reflecting plate 53 to generate electricity. The direct light from the blue LED module 21 is not incident on the light guide plate 52 from the blue LED module 21 but leaked out therefrom. Out of the light energy 68 incident on the light guide plate 52 from the blue LED module 21, the reflected light from the light reflecting plate 53 is the light guided to the bottom surface portion of the light guide plate 52 and reflected therefrom by the light reflecting plate 53. The organic thin film transparent solar cells 100a, 100b absorb the UV light energy 73 from the sunlight or outdoor lighting (street lamp, mercury lamp, etc.), to self-generate electricity by the photovoltaic effect. Further, the organic thin film transparent solar cells 100a, 100b absorb the UV light energy 73 from the indoor lighting (Fluorescent light, LED lighting etc.) to self-generate electricity by the photovoltaic effect.

Note that this embodiment employs a configuration in which a combination of the dye sensitized transparent solar cell 95 and the organic thin film transparent solar cell 100a, 100b are combined, but the configuration is not limited thereto, and it is also possible to employ a configuration using the dye sensitized transparent solar cell 95 alone, a configuration in which the dye sensitized transparent solar cell 95 and the organic thin film transparent solar cell 100a are combined, or a configuration in which the dye-sensitized transparent solar cell 95 and organic thin film transparent solar cell 100b are combined.

Further, in this embodiment, the blue LED module 21 is installed in the upper part of the frame 30, but the installation area is not limited thereto, and the blue LED module 21 can be installed in a place which seems to be the most preferable, at one end side of any one of upper, lower, left and right sides of the frame 30.

### (Electric Circuit)

The power control unit 112 controls the electric power to be supplied to the blue LED module 21 (blue LED package 2) which is the light source, and includes the commercial electric power as one of the electric powers to be controlled, and has an AC/DC converter 110 and a DC controller 111. The power control unit 112 captures the commercial electric power and the electric power generated by the transparent solar cells 95, 100a, 100b, and supplies the captured electric power to the power storage device 121. The AC/DC converter 110 converts the electric power into DC power upon receiving supply of the commercial electric power (AC). The DC power converted by the AC/DC converter 110 is stored in the lithium ion storage battery 120 of the power storage device 121. The DC controller 111 controls so that the photovoltaic power generated by the transparent solar cells 95, 100a, 100b is adjusted so as to be compatible with the blue LED module 21. The electric power controlled by the DC controller 111 is stored in the lithium ion storage battery 120 of the power storage device 121.

The power storage device 121 includes a lithium ion storage battery 120 that stores electricity upon receiving supply of the electric power from the power control unit 112, and supplies the electric power stored in the lithium ion storage battery 120 to the blue LED package 2 of the blue LED module 21. The lithium ion storage battery 120 stores the electric power supplied from the AC/DC converter 110 and the DC controller 111 of the power control unit 112. The electric power stored in the lithium ion storage battery 120 is supplied to the blue LED module 21. The electric power supplied to the blue LED module 21 is consumed to cause each blue LED package 2 to emit light (light up the blue LED module 21).

Further, when a charged amount of the lithium ion battery 120 reaches a fully charged state upon receiving supply of the electric power from the power control unit 112, the power storage device 121, by itself, has an overcharge prevention function of stopping supply of the electric power from the power control unit 112.

In the second embodiment of the present invention, each blue LED package 2 emits the light energy 68 by supplying the commercial electric power stored in the lithium ion storage battery 120 to the blue LED module 21 by the power storage device 121 via the AC/DC converter 110. Then, most of the light energy 68 emitted from the blue LED package 2 is incident on the light guide plate 52 and guided to the liquid crystal panel 50 side, which is then incident on the dye sensitized transparent solar cell 95 as guided light. However, in addition, there is leak light which is not incident on the light guide plate 52, and such leak light is incident on the dye sensitized transparent solar cell 95 as direct light from the blue LED module 21. Further, a part of the light energy 68 incident on the light guide plate 52 from the blue LED package 2 is guided to the bottom side of the light guide plate 52, and reflected light reflected therefrom by the light reflecting plate 53 toward the liquid crystal panel 50 is incident on the dye sensitized transparent solar cell 95. Thereby, the dye sensitized transparent solar cell 95 absorbs not only the light guided by the light guide plate 52 but also the light energy 68 of both the direct light from the blue LED module 21 and the reflected light from the light reflecting plate 53, to generate electricity. The electric power generated by the dye sensitized transparent solar cell 95 is stored in the lithium ion storage battery 120, and is used for the light emission by the blue LED module 21. Thereby, the light energy emitted by the blue LED module 21 is reused by the dye sensitized transparent solar cell 95 to self-generate electricity, and it is possible to realize further power saving.

Meanwhile, the organic thin film transparent solar cell 100a and the organic thin film transparent solar cell 100b each absorbs the UV light energy 73 from the sunlight by being exposed to daylight sunlight, to generate the photovoltaic power by the photovoltaic effect. Further, the organic thin film transparent solar cell 100a and the organic thin film transparent solar cell 100b each absorbs the UV light energy 73 emitted from outdoor lighting or indoor lighting at nighttime, to generate the photovoltaic power by the photovoltaic effect. The photovoltaic power generated by the dye sensitized transparent solar cell 95 and the organic thin film transparent solar cells 100a, 100b is captured into the power storage device 121 via the DC controller 111, and stored in the lithium ion power storage battery 120. Thereby, it is possible to achieve a long life of the discharge capacity of the lithium ion storage battery 120. Further, even if supply of the commercial electric power is cut off due to long-term disaster or the like and the charged amount in the lithium-ion secondary battery 120 becomes zero, it is possible to restore the lost charged amount of the lithium ion storage battery 120 by absorbing the UV light energy 73 from the sunlight or the like by at least one of the organic thin film transparent solar cell 100a and the organic thin film transparent solar cell 100b to self-generate the photovoltaic power, and storing the self-generated photovoltaic power in the lithium ion storage battery 120.

Note that in the above-described second embodiment, the blue LED module (blue LED package) is used as an LED module (LED package) which is a light source for illumination, but the LED module is not limited thereto, and a near UV light LED module (near UV light LED package), a purple LED module (purple LED package), a near infrared LED module (near infrared LED package), or the like may also be used. Further, in the second embodiment, the liquid crystal panel is used as a display panel, but the display panel is not limited thereto, and for example, a picture display panel may also be used. The picture display panel is a transparent or semitransparent panel used in an internally illuminated signboard or the like, and a picture to be displayed as a signboard is formed. Further, in the second embodiment, the lithium ion storage battery is used as an example of a storage battery (secondary battery), but other storage batteries (for example, lead storage battery, nickel storage battery, etc.) may also be used as long as the storage capacity and charge/discharge capacity are excellent. Further, in the second embodiment, the dye sensitized transparent solar cell and organic thin film transparent solar cell are used as transparent solar cells, but the transparent solar cells are not limited thereto, and transparent solar cells such as transparent innovative solar cells, transparent compound solar cells, transparent thin film solar cells, etc. can be widely used.

### Third Embodiment

Next, a self-generated lighting device according to a third embodiment of the present invention will be described.

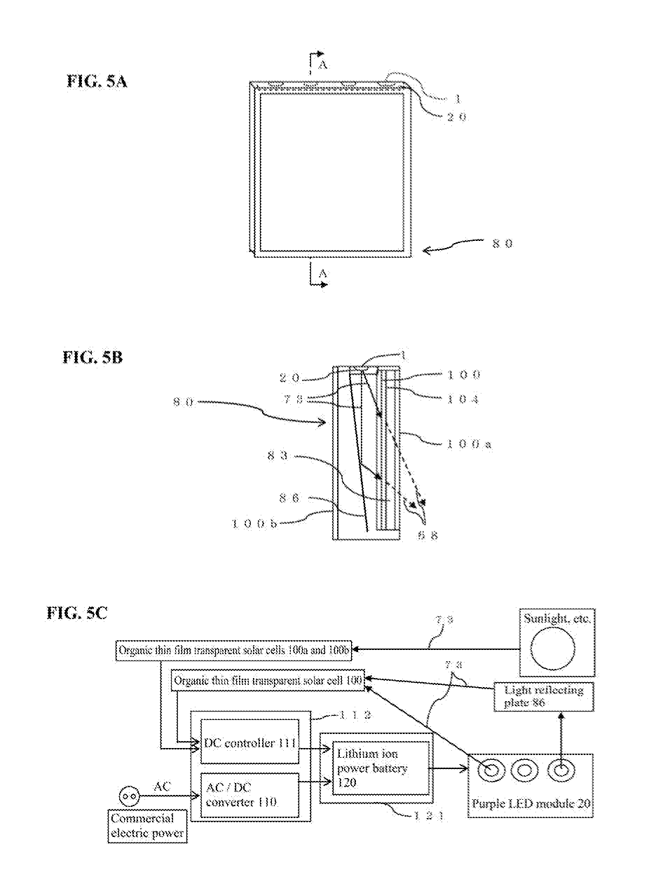

FIG. 5A is a schematic perspective view including a frame of a self-generated lighting device according to a third embodiment of the present invention, FIG. 5B is a cross-sectional view taken along the line A-A of FIG. 5A, and FIG. 5C is a schematic view showing a configuration example of an electric circuit of the self-generated lighting device according to the third embodiment of the present invention. Note that in this third embodiment, elements that are different from those of the first embodiment will be mainly described, elements that are substantially the same as the elements described in the first embodiment will be given the same reference numerals, and description thereof will be omitted as much as possible.

The self-generated lighting device according to the third embodiment of the present invention includes: a purple LED module 20; a frame 80; a picture display panel 83; a light reflecting plate 86; organic thin film transparent solar cells 100, 100a, 100b, and a transparent UV cut film 104.

The purple LED module 20 is formed by connecting a plurality of surface mount-type purple LED packages 1. The purple LED module 20 is a light source for edge light-type illumination. The purple LED module 20 is provided at one end (an upper part in this embodiment) side of the installation area in the frame 80, and emits and radiates the light energy 73 to the confronting side (lower end side) from the one end side of the frame 80.

The frame 80 has an opening area as an installation area in which the picture display panel 83 to be irradiated and the other equipment are installed, and the organic thin film transparent solar cells 100 and 100a are installed, together with the picture display panel 83. Further, the light reflecting plate 86 is installed in the frame 30, together with the picture display panel 83 to be irradiated. The light reflecting plate 86 is installed so as to face the organic thin film transparent solar cell 100.

The picture display panel 83 is a panel on which a picture to be displayed on an internally illuminated signboard is formed, and is attached to the frame 80. The picture display panel 83 is formed using a transparent or translucent panel having light transparency, and a picture is formed on the display surface side. The display surface of the picture display panel 83 is disposed outward.

The light reflecting plate 86 has a reflecting surface on the side facing the organic thin film transparent solar cell 100. The reflecting surface of the light reflecting plate 86 is uniformly formed in a planar shape, so that a part of the UV light energy 73 emitted and radiated from the purple LED module 20 is forcibly reflected by the reflecting surface toward the picture display panel 83 side. The light reflecting plate 86 is installed by inclining the reflecting surface obliquely at a predetermined angle, so that a facing distance (horizontal distance) between the reflecting surface and the organic thin film transparent solar cell 100 is gradually decreased from the upper end toward the lower end of the frame 80. Note that the light reflecting plate 86 may have a configuration capable of arbitrarily changing the inclination angle of its reflecting surface, for example, by rotatably supporting one end (the upper end in this embodiment) of the light reflecting plate 86 using an instrument having a turning property such as a hinge.

Each of the organic thin film transparent solar cells 100, 100a, 100b is formed in a planar shape. The organic thin film transparent solar cell 100 absorbs the UV energy 73 emitted and radiated from each purple LED package 1 connected to a plurality of purple LED modules 20, to self-generate the photovoltaic power by the photovoltaic effect. Specifically, the organic thin film transparent solar cell 100 absorbs the UV light energy 73 of both the direct light from the purple LED module 20 and the reflected light from the light reflecting plate 86, to generate electricity. The organic thin film transparent solar cells 100a, 100b absorb the UV light energy 73 from the sunlight or outdoor lighting (street lamp, mercury lamp, etc.), to self-generate electricity by the photovoltaic effect. Further, the organic thin film transparent solar cells 100a, 100b absorb the UV light energy 73 from Indoor lighting (fluorescent light, LED lighting etc.), to self-generate electricity by the photovoltaic effect.

The organic thin film transparent solar cell 100 is disposed in the frame 80 so as to face the light reflecting plate 86. The organic thin film transparent solar cell 100 is disposed on the inner surface of the picture display panel 83 interposing the transparent UV cut film 104, and the organic thin film transparent solar cell 100a is disposed on the outer surface of the picture display panel 83. Thereby, the UV light energy 73 emitted from each purple LED package 1 of the purple LED module 20 is absorbed by the organic thin film transparent solar cell 100, and the UV light which cannot be completely absorbed there is absorbed and eliminated by the transparent UV cut film 104. Accordingly, the picture display panel 83 is irradiated with the light energy 68 which does not contain the UV light. The organic thin film transparent solar cell 100b is installed on the back side (the side opposite to the opening of the installation area) of the frame 80.

The transparent UV cut film 104 is formed outside of the organic thin film transparent solar cell 100, as seen from the surface mount-type purple LED package 1. The transparent UV cut film 104 absorbs and eliminates the UV light transmitted through the organic thin film transparent solar cell 100. The transparent UV cut film 104 absorbs and eliminates the remaining UV light after being absorbed by the organic thin film transparent solar cell 100 to generate photovoltaic power, and transmits the light energy 68 as it is not containing the UV light. Thereby, the transparent UV cut film 104 suppresses a bad influence of emitting UV lights toward the picture display panel 83 or the human body existing in front of the transparent UV cut film 104.

Note that, this embodiment employs a configuration in which three organic thin film transparent solar cells 100, 100a, and 100b are combined, but the configuration is not limited thereto, and it is also possible to employ a configuration using the organic thin film transparent solar cell 100 alone, a configuration in which the organic thin film transparent solar cell 100 and the organic thin film transparent solar cell 100a are combined, or a configuration in which the organic thin film transparent solar cell 100 and the organic thin film transparent solar cell 100b are combined.

### (Electric Circuit)

The power control unit 112 controls the electric power to be supplied to the purple LED module 20 (purple LED package 1) which is the light source, and includes the commercial electric power as one of the electric powers to be controlled, and has an AC/DC converter 110 and a DC controller 111. The power control unit 112 captures the commercial electric power and the electric power generated by the transparent solar cells 100, 100a, 100b, and supplies the captured electric power to the power storage device 121. The AC/DC converter 110 converts the electric power into DC power upon receiving supply of the commercial electric power (AC). The DC power converted by the AC/DC converter 110 is stored in the lithium ion storage battery 120 of the power storage device 121. The DC controller 111 controls so that the photovoltaic power generated by the transparent solar cells 100, 100a, 100b is adjusted so as to be compatible with the purple LED module 20. The electric power controlled by the DC controller 111 is stored in the lithium ion storage battery 120 of the power storage device 121.

The power storage device 121 includes a lithium ion storage battery 120 that stores electricity upon receiving supply of the electric power from the power control unit 112, and supplies the electric power stored in the lithium ion storage battery 120 to the purple LED package 1 of the purple LED module 20. The lithium ion storage battery 120 stores electricity supplied from the AC/DC converter 110 and the DC controller 111 of the power control unit 112. The electric power stored in the lithium ion storage battery 120 is supplied to the purple LED module 20. The electric power supplied to the purple LED module 20 is consumed to cause each purple LED package 1 to emit light (light up the purple LED module 20).

Further, the power storage device 121 has a detecting function of detecting stop of supply of the electric power from the power control unit 112, and/or power failure, in addition to on (energizing)/off (cutoff) function of a power switch. When the stop of supply of the electric power from the power control unit 112 and/or the power failure is detected by the detecting function, the power storage device 121 has an endless function of always turning on the purple LED package 1 by continuously supplying the electric power stored in the lithium ion storage battery 120 to purple LED package 1 of the purple LED module 20 and resuming supply of the electric power to the purple LED package 1 of the purple LED module 20 upon receiving supply of the electric power generated by the organic thin film transparent solar cell 100 by absorption of the UV light energy 73 emitted from the purple LED package 1 during the on-state. Note that the power switch is a switch for turning on the self-generated lighting device in the on-state and turning off the self-generated lighting device in the off state. Further, “always on-state” means to keep the light source for illumination on, before and after detecting with the detecting function.

Further, when a charged amount of the lithium ion battery 120 reaches a fully charged state upon receiving supply of the electric power from the power control unit 112, the power storage device 121, by itself, has an overcharge prevention function of stopping supply of the electric power from the power control unit 112. Further, when supply of the electric power from the power control unit 112 is stopped by the overcharge prevention function and thereafter the electric power is consumed from the fully charged state to become storable, the power storage device 121 has a function of storing electricity upon receiving supply of the electric power from the power control unit 112, the electric power being generated by the organic thin film transparent solar cell 100 and the organic thin film transparent solar cells 100a, 100b, and when the storage amount of the lithium ion storage battery 120 is decreased to a preset remaining charged amount during this storage, the power storage device 121 has a function of resuming supply of the commercial electric power to the purple LED package 1 of the purple LED module 20 upon receiving supply of the commercial electric power from the power control unit 112. For example, the remaining charged amount may be set within a range of 30% or more and 50% or less when the fully charged amount in the fully charged state is taken as 100%. Note that the reason why a range of 30% or more and 50% or less is set for the setting of the remaining charged amount is because, there is a possibility that a proper value of the remaining power storage amount may be changed depending on an installing location and an infrastructure environment of the self-generated lighting device. Specifically, the time required for recovery after power failure tends to be relatively short in urban areas and relatively long in mountainous areas, and in this case, it is better to set the remaining charged amount to about 30% in the urban areas, and it is better to set the remaining charged amount to about 50% in the mountainous areas. Therefore, it is desirable to appropriately set the remaining charged amount according to a location where the purple LED module 20 is used.

In the third embodiment of the present invention, each purple LED package 1 emits the UV light energy 73 by supplying the commercial electric power to the purple LED module 20 via the AC/DC converter 110, the commercial electric power being stored in the lithium ion storage battery 120. Then, a part of the UV light energy 73 emitted from the purple LED package 1 is incident on the organic thin film transparent solar cell 100 as a direct light from the purple LED package 1, and the other UV light energy 73 is incident on the organic thin film transparent solar cell 100 as a reflected light from the light reflecting plate 86. Thereby, the organic thin film transparent solar cell 100 absorbs the UV light energy 73 of both the direct light and the reflected light to generate electricity. The electric power generated by the organic thin film transparent solar cell 100 is stored in the lithium ion storage battery 120, and is used for the light emission from the purple LED package 1. Thereby, the light energy emitted from the purple LED package 1 is reused by the organic thin film transparent solar cell 100 to self-generate electricity, and further power saving is enabled.

Meanwhile, the organic thin film transparent solar cell 100a and the organic thin film transparent solar cell 100b respectively absorbs the UV light energy 73 from sunlight by being exposed to daylight sunlight to generate the photovoltaic power by the photovoltaic effect. Further, the organic thin film transparent solar cell 100a and the organic thin film transparent solar cell 100b respectively absorbs the UV light energy 73 emitted from outdoor lighting or indoor lighting at night to generate the photovoltaic power by the photovoltaic effect. The photovoltaic power generated by the organic thin film transparent solar cells 100, 100a in this manner, is captured into the power storage device 121 via the DC controller 111, and is stored in the lithium ion storage battery 120. Thereby, it is possible to achieve a long life of the discharge capacity of the lithium ion storage battery 120. Further, even if supply of the commercial electric power is cut off due to long-term disaster or the like and an amount of the stored electricity in the lithium ion storage battery 120 becomes 0, it is possible to restore the lost charged amount of the lithium ion storage battery 120 by storing therein the photovoltaic power which is self-generated by absorbing the UV light energy 73 from the sunlight by at least one of the organic thin film transparent solar cell 100a and the organic thin film transparent solar cell 100b.

Further, even if the power failure occurs while being in the lighting state of the purple LED module 20 (purple LED package 1), the purple LED package 1 emits the UV light energy 73 upon receiving supply of the electric power continuously from the lithium ion storage battery 120, and the organic thin film transparent solar cell 100 repeats generation of electricity by absorption of the UV light energy 73, and stores electricity in the lithium ion storage battery 120. Thereby, it is possible to achieve a longer life of the discharge capacity time of the lithium ion storage battery 120. Further, the purple light package 1 continues to emit the UV light energy 73 until the stored amount of the lithium ion storage battery 120 becomes zero as long as the power switch is not turned off (cut off). Therefore, it is possible to realize the self-generated lighting device having both a function as a lighting device responding to long-term emergency power failure and a power saving function during stop of the supply of the commercial electric power.

Particularly, when the self-generated lighting device of this embodiment is applied to the internally illuminated signboard lighting device, the lighting device is often installed on the wall of a building on the sidewalk in a downtown area. Therefore, if the self-generated lighting device of this embodiment is applied to such an internally illuminated signboard lighting device, it is possible to give a sense of safety and security to the surroundings by illuminating the entrance of the building and the sidewalk brightly at the time of power failure.

In addition in the third embodiment, the purple LED module (purple LED package) is used as an LED module (LED package) which is a light source for illumination, but the LED module is not limited thereto, and a near-UV light LED module (near UV light LED package), a blue LED module (blue LED package), a near-infrared LED module (near-infrared LED package), or the like may also be used. Further, in the third embodiment, the lithium ion storage battery is used as an example of the storage battery (secondary battery), but other storage batteries (for example, lead storage battery, nickel storage battery, etc.) may also be used as long as the storage capacity and charge/discharge capacity are excellent. Further, in the third embodiment, the organic thin film transparent solar cell is used as a transparent solar cell, but the transparent solar cell is not limited thereto, and transparent solar cells such as organic transparent solar cells including dye sensitized transparent solar cells, transparent innovative solar cells, transparent compound-based solar cells, and transparent thin-film solar cells, can be widely used.

### Fourth Embodiment

Next, a self-generated lighting device according to a fourth embodiment of the present invention will be described.

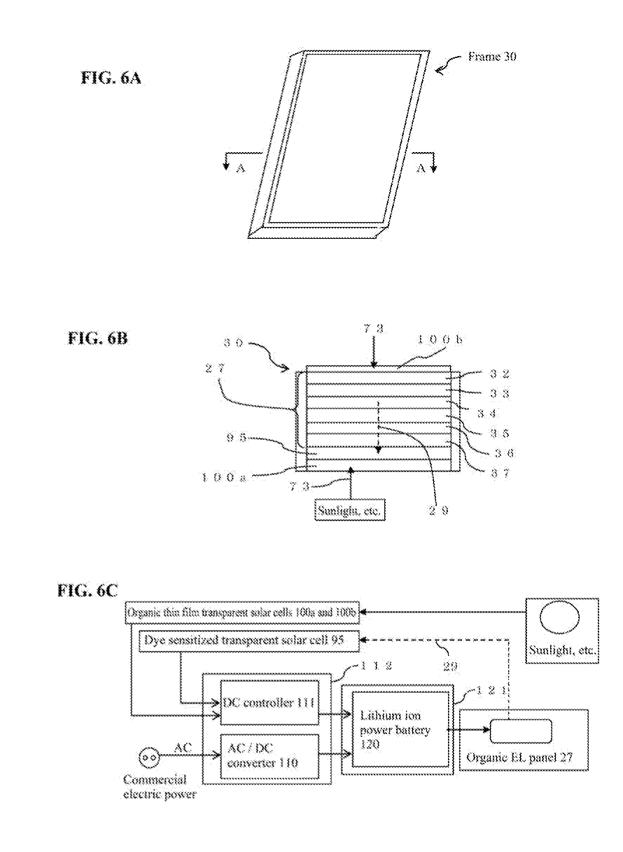

FIG. 6A is a schematic perspective view including the frame of the self-generated lighting device according to the fourth embodiment of the present invention, FIG. 6B is a cross-sectional view taken along the line A-A of FIG. 6A, and FIG. 6C is a schematic view showing a configuration example of an electric circuit of the self-generated lighting device according to the fourth embodiment of the present invention. Note that in the fourth embodiment, elements that are different from those of the first embodiment will be mainly described, elements that are substantially the same as the elements described in the first embodiment will be given the same reference numerals, and description thereof will be omitted as much as possible.

The self-generated lighting device according to the fourth embodiment of the present invention includes: a frame 30, an organic EL panel 27, the dye sensitized transparent solar cell 95, and organic thin film transparent solar cells 100a, 100b.

The frame 30 has an opening area as an installation area in which the dye sensitized transparent solar cell 95 and the organic thin film transparent solar cell 100a are installed together with the organic EL panel 27. Further, the organic thin film transparent solar cell 100b is installed on the back side (the side opposite to the opening of the installation region) of the frame 30.

The organic EL panel 27 is a self-luminous type panel installed in the installation area in the frame 30. The organic EL panel 27 emits light energy 29 of full color upon receiving supply of the electric power. The organic EL panel 27 includes: a metal electrode 32, an organic electron transporting layer 33, an organic light emitting layer 34, an organic hole transporting layer 35, an ITO (indium tin oxide) transparent electrode 36, and a transparent substrate 37. The organic light emitting layer 34 has a light emitting layer of each color of R (red), G (green), and B (blue). The ITO transparent electrode 36, the organic hole transport layer 35, the organic light emitting layer 34, the organic electron transport layer 33, and the metal electrode 32 are stacked on the transparent substrate 37 in this order. The organic EL panel 27 emits the light energy 29 of full color in such a manner that electrons carried from the metal electrode 32 through the organic electron transport layer 33 and holes carried from the ITO transparent electrode 36 through the organic hole transport layer 35 are combined in the organic light emitting layer 34, and a light emitting material of the organic light emitting layer 34 is excited by the energy resulting from this combination.

The dye sensitized transparent solar cell 95 is formed in a planar shape on the outer surface of the organic EL panel 27 with the light absorption surface facing inward. The organic thin film transparent solar cell 100a is formed in a planar shape on the outer surface of the organic EL panel 27 with its light absorption surface facing outward. The organic thin film transparent solar cell 100b is formed in a planar shape on the surface opposite to the opening of the installation area in the frame 30.

The dye sensitized transparent solar cell 95 is disposed in the light emission direction of the organic EL panel 27. Specifically, the dye sensitized transparent solar cell 95 is formed on one main surface of the transparent substrate 37, and on the side opposite to the ITO transparent electrode 36. The dye sensitized transparent solar cell 95 is formed in a planar shape so as to cover the main surface of the transparent substrate 37. The dye sensitized transparent solar cell 95 absorbs light energy 29 emitted from the organic EL panel 27 to generate the photovoltaic power by the photovoltaic effect.

The organic thin film transparent solar cell 100a is laminated on the transparent substrate 37, interposing the dye sensitized transparent solar cell 95. The dye sensitized transparent solar cell 95 and the organic thin film transparent solar cell 100a are integrally formed with their light absorption surfaces in opposite directions. A light absorbing surface of the dye sensitized transparent solar cell 95 is disposed facing toward the organic EL panel 27 (organic light emitting layer 34), and the light absorbing surface of the organic thin film transparent solar cell 100a is disposed outwardly so as to be opposite to the organic EL panel 27. The organic thin film transparent solar cell 100a is formed in a planar shape so as to cover the dye sensitized transparent solar cell 95. The organic thin film transparent solar cell 100b is formed in a planar shape so as to cover the metal electrode 32 on the back side of the frame 30. The light absorbing surface of the organic thin film transparent solar cell 100b is disposed outwardly so as to be opposite to the metal electrode 32. The organic thin film transparent solar cells 100a, 100b absorb the UV light energy 73 from the sunlight or outdoor lighting (street lamp, mercury lamp, etc.), to self-generate electricity by the photovoltaic effect. Further, the organic thin film transparent solar cells 100a, 100b absorb the UV light energy 73 from Indoor lighting (fluorescent light, LED lighting etc.), to self-generate electricity by the photovoltaic effect.

Note that this embodiment employs a configuration in which a combination of the dye sensitized transparent solar cell 95 and the organic thin film transparent solar cell 100a, 100b are combined, but the configuration is not limited thereto, and it is also possible to employ a configuration using the dye sensitized transparent solar cell 95 alone, a configuration in which the dye sensitized transparent solar cell 95 and the organic thin film transparent solar cell 100a are combined, or a configuration in which the dye-sensitized transparent solar cell 95 and organic thin film transparent solar cell 100b are combined.

### (Electric Circuit)

The power control unit 112 controls the electric power to be supplied to the organic EL panel 27, and includes the commercial electric power as one of the electric powers to be controlled, and has the AC/DC converter 110 and the DC controller 111. The power control unit 112 captures the commercial electric power and the electric power generated by the transparent solar cells 95, 100a, and 100b, and supplies the captured electric power to the power storage device 121. The AC/DC converter 110 converts the commercial electric power (AC) to DC power upon receiving supply of the commercial electric power (AC). The DC power converted by the AC/DC converter 110 is stored in the lithium ion storage battery 120 of the power storage device 121. The DC controller 111 controls so that the photovoltaic power generated by the transparent solar cells 95, 100a, and 100b is compatible with the organic EL panel 27. The electric power controlled by the DC controller 111 is stored in the lithium ion storage battery 120 of the power storage device 121.

The power storage device 121 includes the lithium ion power storage battery 120 that stores electricity upon receiving supply of the electric power from the power control unit 112, and supplies the electric power stored in the lithium ion power storage battery 120 to the organic EL panel 27. The lithium ion storage battery 120 stores the electric power supplied from the AC/DC converter 110 and the DC controller 111 of the power control unit 112. The electric power stored in the lithium ion storage battery 120 is supplied to the organic EL panel 27. The electric power supplied to the organic EL panel 27 is consumed to cause the organic light emitting layer 34 of the organic EL panel 27 to emit light.

Further, when a charged amount of the lithium ion battery 120 reaches a fully charged state upon receiving supply of the electric power from the power control unit 112, the power storage device 121, by itself, has an overcharge prevention function of stopping supply of the electric power from the power control unit 112.

In the fourth embodiment of the present invention, the organic EL panel 27 emits the light energy 29 of full color, when the power storage device 121 supplies the commercial electric power stored in the lithium ion storage battery 120 to the organic EL panel 27 via the AC/DC converter 110. Then, the dye sensitized transparent solar cell 95 absorbs the light energy 29 emitted from the organic EL panel 27 to generate the photovoltaic power by the photovoltaic effect. The electric power generated by the dye sensitized transparent solar cell 95 is stored in the lithium ion storage battery 120, and is used for the light emission from the organic EL panel 27. Thereby, the light energy emitted by the organic EL panel 27 is reused by the dye sensitized transparent solar cell 95 to self-generate electricity, and further it is possible to realize the power saving.

Meanwhile, the organic thin film transparent solar cell 100a and the organic thin film transparent solar cell 100b respectively absorbs the UV light energy 73 from sunlight by being exposed to daylight sunlight to generate the photovoltaic power by the photovoltaic effect. Further, the organic thin film transparent solar cell 100a and the organic thin film transparent solar cell 100b respectively absorbs the UV light energy 73 emitted from outdoor lighting or indoor lighting at night to generate the photovoltaic power by the photovoltaic effect. The photovoltaic power generated by the organic thin film transparent solar cells 95, 100a, 100b in this manner, is captured into the power storage device 121 via the DC controller 111, and is stored in the lithium ion storage battery 120. Thereby, it is possible to achieve a long life of the discharge capacity of the lithium ion storage battery 120. Further, even if supply of the commercial electric power is cut off due to long-term disaster or the like and an amount of the stored electricity in the lithium ion storage battery 120 becomes 0, it is possible to restore the lost charged amount of the lithium ion storage battery 120 by storing therein the photovoltaic power which is self-generated by absorbing the UV light energy 73 from the sunlight by at least one of the organic thin film transparent solar cell 100a and the organic thin film transparent solar cell 100b.

Note that in the above-described fourth embodiment, the lithium ion storage battery is used as an example of the power storage battery (secondary battery), but other storage batteries (for example, lead storage battery, nickel storage battery, etc.) may also be used as long as the storage capacity and charge/discharge capacity are excellent. Further, in the fourth embodiment, the dye sensitized transparent solar cell and the organic thin film transparent solar cell are used as transparent solar cells, but the transparent solar cells are not limited thereto, and transparent solar cells such as transparent innovative solar cells, transparent compound-based solar cells, transparent thin-film solar cells, etc., can be widely used.

Supplementary descriptions of the present invention will be described below.

### (Supplementary Description 1)

There is provided a self-generated lighting device, including:

a frame having an opening area as an installation area in which an object to be irradiated is installed;

a light source for illumination which is provided in the frame, and emits light upon receiving supply of electric power;

a transparent solar cell that absorbs light energy to generate electricity;

a display panel which is installed in the installation area in the frame as the object to be irradiated, and which displays a predetermined image upon receiving supply of the light energy emitted from the light source;

a power control unit that controls electric power supplied to the light source and includes at least commercial electric power as one of electric powers to be controlled; and

a power storage device that includes a power storage battery that stores electricity upon receiving supply of the electric power from the power control unit, and supplies the electric power stored in the power storage battery to the light source,

wherein the transparent solar cell includes at least a first transparent solar cell among the first transparent solar cell formed in a planar shape on an inner surface of the display panel, a second transparent solar cell formed in a planar shape on an outer surface of the display panel, and a third solar cell formed in a planar shape on a surface opposite side to the opening of the installation area in the frame,

the first transparent solar cell absorbs light energy emitted from the light source to generate electricity, and

the second transparent solar cell and the third solar cell absorb light energy from sunlight or outdoor lighting to generate electricity, and absorb light energy from indoor lighting to generate electricity, and

the power storage device stores electricity in the power storage battery, upon receiving supply of the electric power generated by at least the first transparent solar cell among the first transparent solar cell, the second transparent solar cell, and the third solar cell.

### (Supplementary Description 2)

There is provided the self-generated lighting device according to the supplementary description 1, wherein when supply of the commercial electric power is cut off due to long-term disaster or the like, a lost charged amount of the power storage battery is restored by receiving supply of the electric power from the power control unit, the electric power being generated by absorbing the light energy from the sunlight or the outdoor lighting by at least one of the second transparent solar cell and the third solar cell.

### INDUSTRIAL APPLICABILITY

Light sources for currently used liquid crystal light sources, light sources for illumination such as internally illuminated signboards, or light sources such as organic light emitting diodes, do not reuse the light energy emitted by itself and needs much power consumption. The self-generated lighting device of the present invention can self-generate electricity by reusing the light energy emitted by itself. Further, by providing a transparent solar cell that absorbs the light energy from the light source to generate electricity, it is possible to calculate stable self-generation without being influenced by the weather. Further, by using the solar cell that absorbs light energy of sunlight or outdoor lighting outside of the frame, or light energy of indoor lighting to generate electricity, it is possible to realize enormous power saving, which can help to prevent global warming.

### DESCRIPTION OF SIGNS AND NUMERALS

1 . . . Purple LED package
2 . . . Blue LED package
10 . . . Purple LED element
20 . . . purple LED module
21 . . . Blue LED module
27 . . . organic EL panel
30 . . . Frame
50 . . . liquid crystal panel
52 . . . light guide plate
53 . . . light reflector
68 . . . light energy
73 . . . UV light energy
80 . . . Frame
83 . . . Picture display panel
86 . . . Light reflecting plate
95 . . . Dye sensitized transparent solar cell
100, 100a, 100b . . . Organic thin film transparent solar cell
110 . . . AC/DC converter
111 . . . DC controller
112 . . . Power control unit
120 . . . Lithium ion storage battery
121 . . . Power storage device

1. A self-generated lighting device, comprising:
a frame having an opening area as an installation area in which an object to be irradiated is installed;
a light source for illumination which is provided in the frame, and emits light upon receiving supply of electric power;
a solar cell that absorbs light energy to generate electricity;
a display panel which is installed in the installation area in the frame as the object to be irradiated, and which displays a predetermined image upon receiving supply of the light energy emitted from the light source;
a light guide plate provided in the frame;
a light reflecting plate formed on a bottom surface portion of the light guide plate;
a power control unit that controls electric power supplied to the light source and includes at least commercial electric power as one of electric powers to be controlled; and
a power storage device that includes a power storage battery that stores electricity upon receiving supply of the electric power from the power control unit, and supplies the electric power stored in the power storage battery to the light source,
wherein the light source is provided at one end of the installation area in the frame, and emits light energy toward a confronting side from the one end side,
the light guide plate guides the light energy emitted from the light source toward the display panel, and
out of the light energy emitted from the light source, the light reflecting plate reflects the light energy toward the display panel, the light energy being guided toward a bottom surface portion of the light guide plate, and
the solar cell absorbs light energy of both direct light from the light source and reflected light from the light reflecting plate, to generate electricity.

2. The self-generated lighting device according to claim 1, wherein when a charged amount of the power storage battery reaches a fully charged state upon receiving supply of the electric power from the power control unit, the power storage device, by itself, has an overcharge prevention function of stopping supply of the electric power from the power control unit.

3. The self-generated lighting device according to claim 1,
wherein the solar cell includes at least a first solar cell among a transparent first solar cell formed in a planar shape on an inner surface of the display panel, a transparent second solar cell formed in a planar shape on an outer surface of the display panel, and a transparent or opaque third solar cell formed in a planar shape on a surface opposite side to the opening of the installation area in the frame, and
the first solar cell absorbs the light energy emitted from the light source to generate electricity,
when the solar cell includes the second solar cell and the third solar cell, the second solar cell and the third solar cell absorb light energy from sunlight or outdoor lighting to generate electricity, and absorb light energy from indoor lighting to generate electricity, and
the power storage device stores electricity in the power storage battery upon receiving supply of the electric power from the power control unit, the electric power being generated by at least the first solar cell among the first solar cell, the second solar cell, and the third solar cell.

4. The self-generated lighting device according to claim 3,
wherein when supply of the commercial electric power is cut off due to long-term disaster or the like, the power storage device restores a charged amount of the power storage battery, upon receiving supply of the electric power from the power control unit, the electric power being generated by absorbing the light energy from the sunlight or the outdoor lighting by at least one of the second solar cell and the third solar cell.

5. A self-generating lighting device, comprising:
a frame having an opening area as an installation area in which an object to be irradiated is installed;
a light source for illumination which is provided in the frame, and emits light upon receiving supply of electric power;
a solar cell that absorbs light energy to generate electricity;
a display panel which is installed in the installation area in the frame as the object to be irradiated, and which displays a predetermined image upon receiving supply of the light energy;
a light reflecting plate provided in the frame;
a power control unit that controls electric power to be supplied to the light source, and includes at least commercial electric power as one of electric powers to be controlled; and
a power storage device that includes a power storage battery that stores electricity upon receiving supply of the electric power from the power control unit, and supplies the electric power stored in the power storage battery to the light source,
wherein the light source is provided at one end of the installation area in the frame, and emits the light energy toward a confronting side from the one end of the installation area,
the light reflecting plate has a reflecting surface disposed to face the display panel, with the reflecting surface set obliquely inclined so that a distance between the reflecting surface and the display panel is gradually decreased from one end of the installation area toward the other end confronting thereto, and so that a part of the light energy emitted from the light source, is reflected by the reflecting surface toward the display panel, and
the solar cell absorbs the light energy of both direct light emitted from the light source and reflected light emitted from the light source and reflected by the reflecting surface toward the display panel, to generate electricity.

6. The self-generated lighting device according to claim 5,
wherein the power storage device has a detecting function of detecting stop of supply of the electric power from the power control unit, and/or power failure, in addition to on/off function of a power switch, and has an endless function of always turning on the light source by continuously supplying the electric power stored in the storage battery to the light source when the stop of supply of the electric power from the power control unit and/or power failure is detected by the detecting function, and resuming supply of the electric power to the light source upon receiving supply of the electric power from the power control unit, the electric power being generated by the solar cell by absorbing the light energy emitted from the light source during the on state.

7. The self-generated lighting device according to claim 5,
wherein the solar cell includes at least a transparent first solar cell formed in a planar shape on an inner surface of the display panel, a transparent second solar cell formed in a planar shape on an outer surface of the display panel, and a transparent or opaque third solar cell formed in a planar shape on a surface opposite side to the opening of the installation area in the frame,
the first solar cell absorbs both light energy of the direct light and the reflected light to generate electricity,
when the solar cell includes the second solar cell and the third solar cell, the second and third solar cells absorb light energy from sunlight or outdoor lighting to generate electricity, and absorb light energy from indoor lighting to generate electricity, and
the power storage device stores electricity in the power storage battery upon receiving supply of the electric power from the power control unit, the electric power being generated by at least one solar cell among the first solar cell, the second solar cell, and the third solar cell.

8. A self-generated lighting device, comprising:
a frame having an opening area as an installation area;
a self-luminous panel which is installed in the installation area in the frame and emits light upon receiving supply of the electric power;
a solar cell that absorbs light energy to generate electricity;
a power control unit that controls electric power to be supplied to the panel, and includes at least commercial electric power as one of electric powers to be controlled; and
a power storage device that includes a power storage battery that stores electricity upon receiving supply of the electric power from the power control unit, and supplies the electric power stored in the power storage battery to the panel,
wherein the solar cell includes at least a first solar cell among a transparent first solar cell formed in a planar shape with its light absorbing surface facing inward, a transparent second solar cell formed in a planar shape with its light absorbing surface facing outward, and a transparent or opaque third solar cell formed in a planar shape on a surface opposite side to the opening of the installation area in the frame,
the first solar cell is disposed in a light emitting direction of the panel, and absorbs light energy emitted from the panel to generate electricity,
when the solar cell includes the second solar cell and the third solar cell, the second and third solar cells absorb light energy from sunlight or outdoor lighting to generate electricity, and absorb light energy from indoor lighting to generate electricity, and
the power storage device stores electricity in the power storage battery upon receiving supply of the electric power from the power control unit, the electric power being generated by at least one solar cell among the first solar cell, the second solar cell, and the third solar cell.

9. A self-generated lighting device according to claim 8, wherein when supply of the commercial electric power is cut off due to long-term disaster or the like, the power storage device restores a charged amount of the power storage battery, upon receiving supply of the electric power from the power control unit, the electric power being generated by absorbing the light energy from the sunlight or the outdoor lighting by at least one of the second solar cell and the third solar cell.

10. The self-generated lighting device according to claim 2,
wherein the solar cell includes at least a first solar cell among a transparent first solar cell formed in a planar shape on an inner surface of the display panel, a transparent second solar cell formed in a planar shape on an outer surface of the display panel, and a transparent or opaque third solar cell formed in a planar shape on a surface opposite side to the opening of the installation area in the frame, and
the first solar cell absorbs the light energy emitted from the light source to generate electricity,
when the solar cell includes the second solar cell and the third solar cell, the second solar cell and the third solar cell absorb light energy from sunlight or outdoor lighting to generate electricity, and absorb light energy from indoor lighting to generate electricity, and
the power storage device stores electricity in the power storage battery upon receiving supply of the electric power from the power control unit, the electric power being generated by at least the first solar cell among the first solar cell, the second solar cell, and the third solar cell.

11. The self-generated lighting device according to claim 10,
wherein when supply of the commercial electric power is cut off due to long-term disaster or the like, the power storage device restores a charged amount of the power storage battery, upon receiving supply of the electric power from the power control unit, the electric power being generated by absorbing the light energy from the sunlight or the outdoor lighting by at least one of the second solar cell and the third solar cell.

12. The self-generated lighting device according to claim 6,
wherein the solar cell includes at least a transparent first solar cell formed in a planar shape on an inner surface of the display panel, a transparent second solar cell formed in a planar shape on an outer surface of the display panel, and a transparent or opaque third solar cell formed in a planar shape on a surface opposite side to the opening of the installation area in the frame,
the first solar cell absorbs both light energy of the direct light and the reflected light to generate electricity,
when the solar cell includes the second solar cell and the third solar cell, the second and third solar cells absorb light energy from sunlight or outdoor lighting to generate electricity, and absorb light energy from indoor lighting to generate electricity, and
the power storage device stores electricity in the power storage battery upon receiving supply of the electric power from the power control unit, the electric power being generated by at least one solar cell among the first solar cell, the second solar cell, and the third solar cell.
